(19) United States
(12) Patent Application Publication
(10) Pub. No.: US 2021/0347636 A1
(43) Pub. Date: Nov. 11, 2021

(54) PROCESS FOR MANUFACTURING A DEVICE FOR DETECTING ELECTROMAGNETIC RADIATION, COMPRISING A SUSPENDED DETECTION ELEMENT

(71) Applicant: COMMISSARIAT A L'ENERGIE ATOMIQUE ET AUX ENERGIES ALTERNATIVES, Paris (FR)

(72) Inventors: Sébastien BECKER, Grenoble Cedex 09 (FR); Jean-Jacques YON, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/283,429

(22) PCT Filed: Oct. 10, 2019
(86) PCT No.: PCT/FR2019/052416

§ 371 Date: Apr. 7, 2021

(30) Foreign Application Priority Data
Oct. 12, 2018 (FR) 1859482

(51) Int. Cl. B81C 1/00; G01J 5/02

(52) U.S. Cl. CPC B81C 1/00119; G01J 5/023; G01J 5/024; G01J 5/20; B81C 2201/0133; B81C 2203/0707; B81C 2201/0176; B81C 2201/0109

(57) ABSTRACT

A process for fabricating a device for detecting electromagnetic radiation includes the step of providing a detecting element suspended by a supporting pillar. The pillar has a lateral through-aperture formed via a local break in the continuity of a layer of interest, because of the presence of a jut in a vertical orifice.

### TECHNICAL FIELD

The field of the invention is that of processes for fabricating devices for detecting electromagnetic radiation comprising at least one thermal detector resting on a substrate. The thermal detector comprises at least one detecting element suspended by at least one supporting pillar, and is produced by means of a plurality of sacrificial layers arranged on the substrate and stacked on top of one another. The invention is notably applicable to the field of infrared or terahertz imaging, of thermography, or even of gas detection.

### PRIOR ART

A device for detecting electromagnetic radiation may comprise sensitive pixels each formed from one thermal detector comprising an absorbent membrane that is thermally insulated from the readout substrate. The absorbent membrane comprises an absorber of the electromagnetic radiation to be detected, thermally associated with a thermometric transducer an electrical property of which varies in magnitude as a function of the temperature of the transducer.

Since the temperature of the thermometric transducer is however highly dependent on its environment, the absorbent membrane is thermally insulated from the substrate and from the readout circuit, the latter being placed in the substrate. Thus, the absorbent membrane is generally suspended above the substrate by anchoring pillars 21, and is thermally insulated therefrom by thermally insulating arms. These anchoring pillars 21 and thermally insulating arms also have an electrical function since they ensure the electrical connection of the absorbent membrane to the readout circuit.

It is generally sought to decrease pixel pitch while optimizing the performance of the thermal detectors. To do this, one approach consists in producing a thermal detector comprising a three-dimensional structure suspended above the readout substrate 10, and having a plurality of separate functional stages superposed on one another.

Thus, document WO2009/026505 describes an example of such a thermal detector comprising a reflector located on and in contact with the readout substrate 10, and a three-dimensional structure suspended above the readout substrate by anchoring pillars 21. The three-dimensional structure comprises a first stage in which the thermally insulating arms and the membrane containing the thermometric transducer (here a thermistor material) lie, and a second stage comprising an absorber of the electromagnetic radiation to be detected. A supporting pillar both holds the absorber above the thermistor membrane and thermally connects these two elements. The absorber and the reflector together form an optical cavity that enhances the absorption of the electromagnetic radiation. Furthermore, notches, which are possibly through-notches, are provided in the absorbent layer, so as to decrease the thermal mass of the thermal detector.

Moreover, the article by Li et al. entitled Recent development of ultra small pixel uncooled focal plane array at DRS, Proc. SPIE 2007, Vol. 6542, p.1Y.1-1Y.12, describes a thermal detector similar to that described above, in which the absorber and the supporting pillar seem to be integrally formed from the same material. This absorber thus comprises an upper peripheral segment that extends in a planar manner around a hollow vertical central segment, the latter resting on the thermistor membrane.

Moreover, it is known to produce a detecting device comprising thermal detectors in the context of a so-called above-IC process, i.e. using a process comprising a continuous sequence of microelectronic production operations (deposition, photolithography and etching) carried out on a single readout substrate. The thermal detectors are thus produced by means of various sacrificial layers deposited on the readout substrate and stacked on top of one another, then removed in fine to ensure the suspension of the membrane containing the thermometric transducer above the substrate. An example of such a fabricating process is notably described in patent application EP2743659.

There is a need to provide a process for fabricating an improved detecting device, the one or more thermal detectors of which comprise a detecting element (absorber, etc.) that is suspended above the substrate by at least one supporting pillar, and that are produced by means of sacrificial layers deposited on the substrate and stacked on top of one another.

### DISCLOSURE OF THE INVENTION

The objective of the invention is to at least partially remedy the drawbacks of the prior art, and more particularly to provide a process for fabricating a device for detecting electromagnetic radiation that has an optimized performance while permitting a decrease in the lateral dimensions of the sensitive pixel.

To this end, the subject of the invention is a process for fabricating a device for detecting electromagnetic radiation, the detecting device comprising: a substrate comprising a readout circuit; and at least one thermal detector resting on the substrate, and connected to the readout circuit, comprising a detecting element suspended above the substrate by at least one supporting pillar. The fabricating process comprises the following steps:
depositing, on the substrate, a first sacrificial layer;
producing, on the first sacrificial layer, at least one intermediate pad intended to form a jut, the intermediate pad being made of at least one material sensitive to a chemical etchant used subsequently to etch sacrificial layers;
depositing, on the first sacrificial layer and the intermediate pad, a second sacrificial layer;
producing, by locally etching the first and second sacrificial layers, at least one vertical orifice that is bounded transversely by a lateral border, said orifice being positioned so that a segment of the intermediate pad protrudes into the vertical orifice, thus forming a jut;
carrying out conformal deposition, on the lateral border of the vertical orifice, of a layer of interest that is intended to form the supporting pillar, which layer of interest then defines an empty internal space of the supporting pillar, the jut causing a local break in the continuity of the layer of interest, forming a lateral through-aperture in the supporting pillar;
depositing a sacrificial filling layer, so as to fill the empty internal space of the supporting pillar;
producing, on the second sacrificial layer and the sacrificial filling layer, the detecting element, which rests on and in contact with the supporting pillar;
suspending the detecting element, by etching said sacrificial layers and the intermediate pad using said etchant, the sacrificial filling layer then being etched through the lateral through-aperture.

The following are certain preferred but non-limiting aspects of this fabricating process.

The internal space of the supporting pillar may open onto an upper aperture located opposite the substrate, said upper aperture being obturated by the detecting element.

The layer of interest may have, on the lateral border of the vertical orifice, an average thickness, the jut protruding with respect to the lateral border by a distance at least equal to said average thickness.

The intermediate pad may be made of a material chosen from Ti, Ta₂O₅, and a silicon nitride.

The layer of interest may be deposited by chemical vapor deposition.

The layer of interest may be made of a material chosen from WSi, TiN, and TiW.

The sacrificial layers may be made of a mineral material, and be removed by wet chemical etching in an acidic medium.

Following the step of depositing the sacrificial filling layer, the latter may comprise an upper segment that covers a peripheral segment of the layer of interest, which covers an upper face of the second sacrificial layer around the vertical orifice, and a lower segment that fills the internal space of the supporting pillar.

The process may comprise a step of removing the upper segment of the sacrificial filling layer, so that the lower segment is flush with the peripheral portion of the layer of interest.

The detecting element may be an absorber of the electromagnetic radiation to be detected, the supporting pillar resting on and in contact with a membrane that comprises a thermometric transducer and that is suspended above the substrate by thermally insulating arms, a reflector resting on and in contact with the substrate.

The detecting element may be an absorbent membrane that absorbs the electromagnetic radiation to be detected and that comprises a thermometric transducer, the supporting pillar resting on and in contact with a thermally insulating arm suspended above the substrate by an anchoring pillar, a reflector being placed between the absorbent membrane and the thermally insulating arm.

### BRIEF DESCRIPTION OF THE DRAWINGS

Other aspects, aims, advantages and features of the invention will become more clearly apparent on reading the following detailed description of preferred embodiments thereof, which description is given by way of non-limiting example with reference to the appended drawings, in which:

FIGS. 1A to 1I illustrate various steps of a process for fabricating a detecting device according to a first embodiment, in which the detecting element is an absorber of the thermal detector;

FIGS. 2A to 2H illustrate various steps of a process for fabricating a detecting device according to a second embodiment, in which the detecting element is an absorbent thermistor membrane of the thermal detector.

### DETAILED DISCLOSURE OF PARTICULAR EMBODIMENTS

In the figures and in the remainder of the description, the same references have been used to designate identical or similar elements. In addition, the various elements have not been shown to scale for the sake of clarity of the figures. Moreover, the various embodiments and variants are not mutually exclusive and may be combined with one another. Unless indicated otherwise, the terms “substantially”, “about” and “of the order of” mean to within 10%, and preferably to within 5%. Moreover, the expression “comprising a” must be understood, unless otherwise indicated, to mean “comprising at least one” and not to mean “comprising a single”.

The invention relates to a process for fabricating a device for detecting electromagnetic radiation, infrared or terahertz radiation for example. The detecting device may thus be particularly suitable for detecting infrared radiation in the LWIR range (Long Wavelength InfraRed), i.e. radiation the wavelength of which is comprised between about 8 m and 14 m.

The detecting device comprises one or more thermal detectors, and preferably a matrix array of identical thermal detectors, which rest on a substrate and are connected to a readout circuit located in the substrate. The thermal detectors thus form sensitive pixels that are arranged periodically, and may have a lateral dimension in the plane of the substrate (called the pixel pitch) of the order of a few tens of microns, and for example equal to about 10 μm or even less.

According to the invention, the one or more thermal detectors each comprise a detecting element suspended above the substrate by at least one hollow supporting pillar. The detecting element participates in detecting the electromagnetic radiation of interest. It may thus be, according to a first embodiment, an absorber of the electromagnetic radiation to be detected that is held above a membrane comprising a thermometric transducer, or even, according to a second embodiment, the membrane comprising the thermometric transducer. These various embodiments are described in detail below by way of illustration, and other configurations are possible.

Moreover, the thermal detector advantageously comprises a three-dimensional structure that is suspended above the substrate by the anchoring pillars, and that comprises a plurality of separate functional stages that are superposed on one another, i.e. placed facing and parallel to one another. The detecting element and the supporting pillar, just like the thermometric transducer and the absorber, preferably occupy various stages of the three-dimensional structure.

The invention is thus in particular applicable to thermal detectors comprising a thermometric transducer that is suspended above the substrate by anchoring pillars 21 and that is thermally insulated from the substrate by thermally insulating arms. The anchoring pillars 21 and the thermally insulating arms also ensure the connection of the thermometric transducer to the readout circuit. Generally, a thermometric transducer is an element that has an electrical property that varies with temperature, and may be a thermistor material formed for example from titanium or vanadium oxide, or from amorphous silicon, a capacitor formed by a pyroelectric or ferroelectric material, a diode (p-n or p-i-n junction), or even a metal-oxide-semiconductor field-effect transistor (MOSFET).

In addition, such thermal detectors each comprise one absorber of the electromagnetic radiation to be detected, which is thermally connected to the thermometric transducer. Preferably, the thermal detectors each also comprise a reflector that is arranged facing the absorber so as to form a quarter-wave interference cavity, thus allowing the absorption of the electromagnetic radiation to be detected by the absorber to be maximized.

Moreover, according to the invention, the one or more thermal detectors are produced by means of various sacrificial layers deposited on the substrate and stacked on top of one another, which sacrificial layers are then removed by means of a chemical etchant so as notably to obtain the suspension of the detecting element, and advantageously to obtain the suspension of the three-dimensional structure. According to the invention, the supporting pillar is then hollow and comprises a lateral through-aperture (i.e. one that is not obturated) allowing a segment of a sacrificial filling layer then located in the internal space of the supporting pillar to be removed. Such a fabricating process thus allows the thermal mass of the supporting pillar to be decreased, and therefore the thermal time constant associated with the thermal detector to be optimized. The performance of the detecting device is therefore improved. This is particularly advantageous in the case where, to produce a thermal detector of small pixel pitch, the internal space of the supporting pillar opens, along the Z-axis, onto an upper aperture that is obturated, for example, by the detecting element.

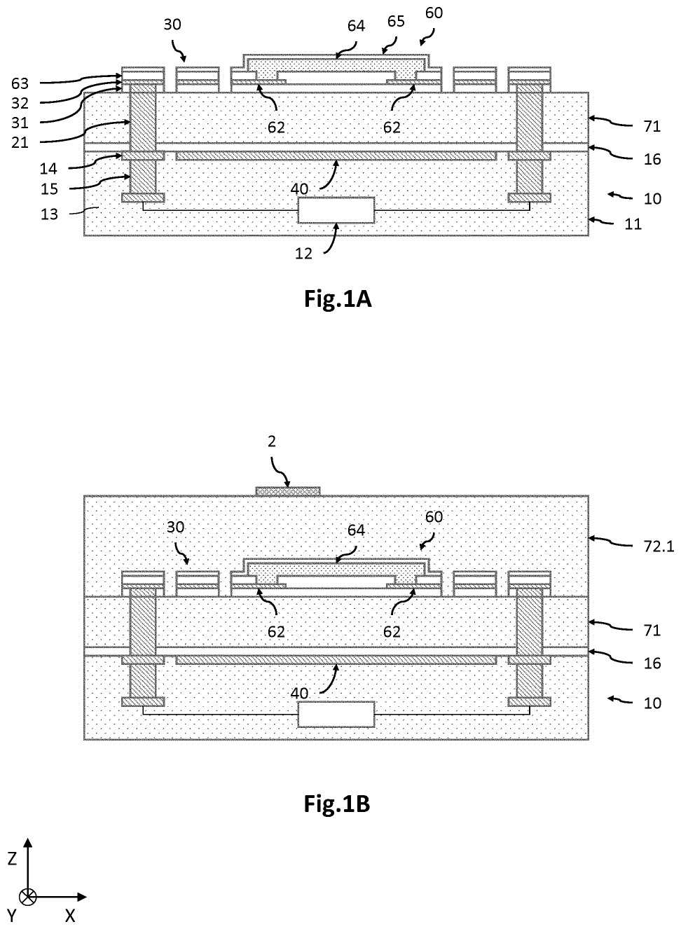

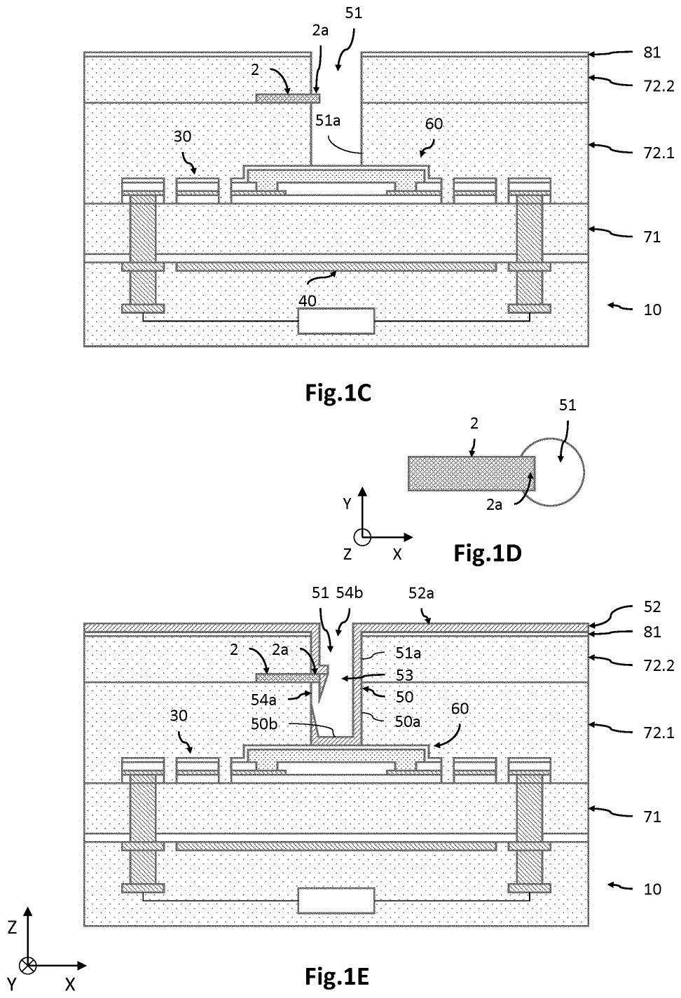

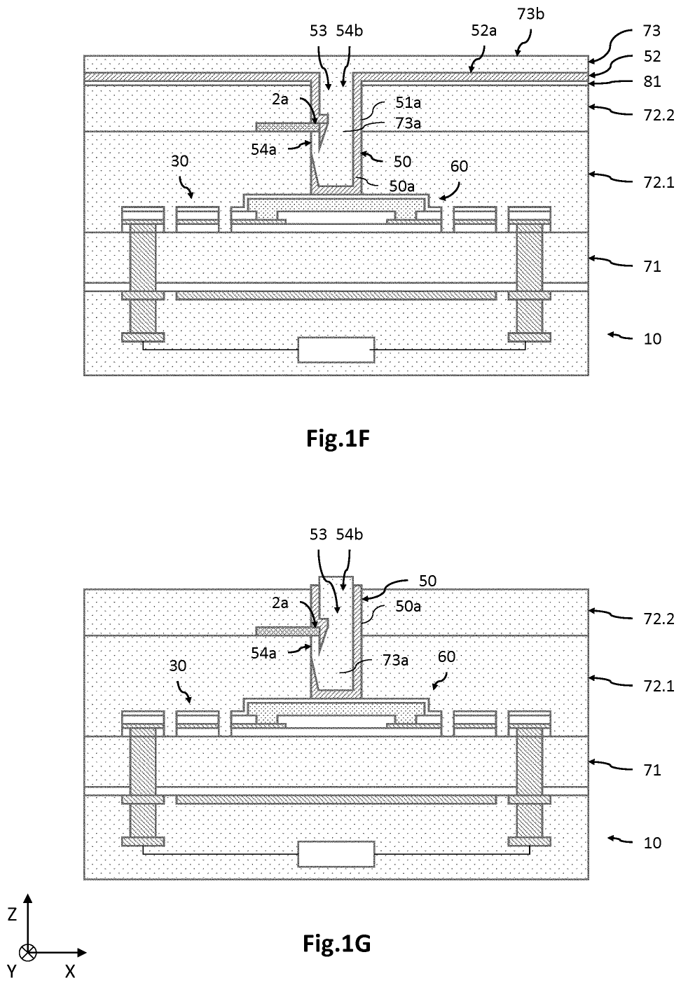

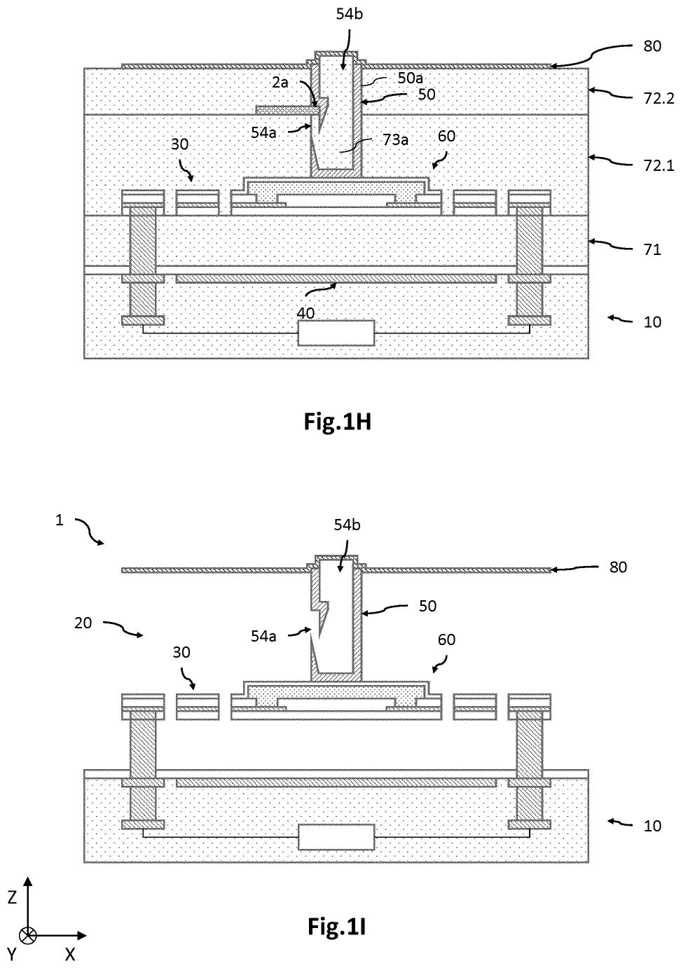

FIGS. 1A to 1I illustrate various steps of a process for fabricating the detecting device 1 according to a first embodiment. A single thermal detector 20 is shown here, but the detecting device 1 advantageously comprises a matrix array of identical thermal detectors 20 (sensitive pixels). In this example, the detecting element corresponds to the absorber 80 of the thermal detector 20. It is held above a membrane 60 containing the thermometric transducer 64, here a thermistor material such as amorphous silicon or a vanadium oxide, by at least one supporting pillar 50.

Moreover, each thermal detector 20 here comprises a three-dimensional structure that is suspended above the readout substrate 10 by anchoring pillars 21, and that comprises two separate functional stages that are superposed on one another. In a lower first stage, the thermally insulating arms 30 and the thermistor membrane 60 extend in a substantially planar manner. In an upper second stage, the detecting element, here the absorber 80 that is suspended above the thermistor membrane 60 by the supporting pillar 50, extends in a substantially planar manner. The latter thus thermally connects the absorber 80 and the thermistor 64. The reflector 40 is here formed from a planar layer resting on and in contact with the readout substrate 10.

In addition, each thermal detector 20 is here produced using mineral sacrificial layers deposited on the readout substrate 10 and stacked on top of one another, these sacrificial layers being intended to be removed subsequently by wet chemical etching in an acidic medium, in hydrofluoric-acid (HF) vapor for example.

Here and for the remainder of the description, an orthogonal three-dimensional direct coordinate system (X, Y, Z) is defined in which the plane (X, Y) is substantially parallel to the main plane of the substrate of the detecting device 1, and in which the Z-axis is oriented in a direction that is substantially orthogonal to the main plane of the readout substrate 10 and is oriented toward the detecting element. In the remainder of the description, the terms “lower” and “upper” will be understood to relate to positions of increasing distance from the substrate in the +Z-direction.

With reference to FIG. 1A, first of all a holder is made for the detecting element (absorber) and for the supporting pillar. Here, it is a question of the lower functional stage of the three-dimensional structure of the thermal detector. To this end, the readout substrate 10 is produced first of all. In this example the readout substrate, which is formed from a carrier substrate 11 containing the readout circuit 12 designed to control and read out the thermal detector, is produced based on silicon.

Here, the readout circuit 12 takes the form of a CMOS integrated circuit located in a carrier substrate 11. It comprises segments 14 of conductive lines, metal lines for example, that are separated from one another by insulating inter-metal layers 13 made of a dielectric 13 that for example may be a mineral material based on silicon, such as a silicon oxide (SiOₓ), a silicon nitride (SiNₓ), or an alloy thereof. It may also comprise active or passive electronic elements (not shown), for example diodes, transistors, capacitors, resistors, etc., connected by electrical interconnects to the thermal detector on the one hand, and to a connection pad (not shown) on the other hand, the latter being intended to connect the detecting device 1 to an external electronic device.

By way of illustration, the conductive segments 14 and the conductive vias 15 may be made, for example, of copper, aluminum or tungsten, for example by means of a damascene process in which trenches formed in the insulating inter-metal layer 13 are filled. The copper or tungsten may optionally be located between sublayers made of titanium nitride inter alia. The conductive segments 14 may be made flush with an upper face of the readout substrate 10 using a CMP (Chemical-Mechanical Polishing) technique.

The reflector 40 of the thermal detector 20 is also produced. The reflector 40 is here formed by a segment 14 of a conductive line of the last interconnect level, said segment being made of a material able to reflect the electromagnetic radiation to be detected. It lies facing the thermistor membrane 60, and is intended to form, with the absorber, a quarter-wave interference cavity with respect to the electromagnetic radiation to be detected.

A protective layer 16 is then deposited so as to cover the insulating inter-metal layer 13, the conductive segments 14, and here the reflector 40. This protective layer 16 here corresponds to an etch-stop layer made of a material that is substantially inert to the chemical etchant used subsequently to remove the mineral sacrificial layers, to HF vapor for example. This protective layer 16 thus forms a hermetic and chemically inert layer. It is electrically insulating in order to avoid any short-circuit between the conductive segments 14. It thus makes it possible to prevent the subjacent mineral insulating layers 13 from being etched during this step of removing sacrificial layers. It may be formed from an aluminum oxide or nitride, from aluminum nitride or trifluoride, or from unintentionally doped amorphous silicon. It may for example be deposited by physical vapor deposition (PVD) and may have a thickness of the order of around ten nanometers to a few hundred nanometers, and for example comprised between 10 nm and 500 nm, and preferably comprised between 20 nm and 100 nm.

Next, the anchoring pillars 21 are produced. To do this, a lower first sacrificial layer 71 is first of all deposited on the readout substrate 10, this sacrificial layer for example being made of a mineral material such as a silicon oxide (SiOₓ) deposited by plasma-enhanced chemical vapor deposition (PECVD). This mineral material is able to be removed by wet chemical etching, in particular by chemical attack in an acidic medium, the etchant preferably being hydrofluoric-acid (HF) vapor. This mineral sacrificial layer 71 is deposited so as to extend continuously over substantially the entire surface of the readout substrate 10 and thus to cover the protective layer 16. The thickness of the sacrificial layer 71 along the Z-axis may be of the order of a few hundred nanometers to a few microns.

The anchoring pillars 21 are then produced in vertical orifices produced beforehand through the sacrificial layer 71 and the protective layer 16. They may be produced by filling the vertical orifices with one or more electrically conductive materials. By way of example, they may each comprise a TiN layer deposited by PVD or metal-organic chemical vapor deposition (MOCVD) on the lateral border and bottom of the vertical orifices, and an electrically conductive copper or tungsten core filling the space bounded transversely by the TiN layer. A step of chemical-mechanical polishing (CMP) then allows excess filling materials to be removed and the upper face formed by the sacrificial layer 71 and the anchoring pillars 21 to be planarized. The anchoring pillars 21 therefore form conductive pads made of at least one electrically conductive material, which extend along the Z-axis from the readout substrate 10 to the thermally insulating arms 30. They make contact with the conductive segments 14, and thus electrically connect the thermal detector 20 to the readout circuit 12.

The thermally insulating arms 30 and the membrane 60 comprising the thermistor material 64 are then produced. The thermally insulating arms 30 thermally insulate the thermistor membrane 60 from the readout substrate 10, electrically connect the thermistor material 64, and participate in holding the thermistor membrane 60 suspended above the readout substrate 10. To do this, here a lower dielectric layer 31 is deposited on the sacrificial layer 71, then a conductive layer 32 and an intermediate dielectric layer 63 are deposited. The electrical contact between the anchoring pillar 21 and the conductive layer 32 is obtained via an aperture produced beforehand through the lower dielectric layer 31 and filled with the material of the conductive layer 32. The conductive layer 32 thus makes contact with the upper end of the anchoring pillars 21. This layer is made of an electrically conductive material, for example TiN with a thickness of a few nanometers to a few tens of nanometers, of 10 nm for example. The lower and intermediate dielectric layers 31, 63 may be made of amorphous silicon, silicon carbide, alumina (Al₂O₃) or aluminum nitride, inter alia. They may have a thickness of a few tens of nanometers, of 20 nm for example, and participate in ensuring the stiffness of the thermally insulating arms 30.

The thermistor membrane 60 is formed from a stack here of the lower insulating layer 31, of two electrodes 62 that were obtained from the conductive layer 32 and that are insulated from each other by a lateral gap, of the intermediate insulating layer 63 covering the electrodes 62 and the lateral gap, except in two apertures that open onto the electrodes 62, and of a thermistor material 64, amorphous silicon or an oxide of vanadium or titanium for example. The thermistor material 64 makes contact with the two electrodes 62 via the apertures. An upper protective layer 65 is then deposited so as to cover the thermistor material 64 and optionally the intermediate dielectric layer 63 level with the thermally insulating arms 30. This layer allows the thermistor material 64 to be protected from the chemical etchant used during the subsequent removal of the mineral sacrificial layers. The dielectric layers 31, 63, the conductive layer 32, and the upper protective layer 65 are then structured by photolithography and localized etching, so as to define the thermally insulating arms 30 in the XY-plane, and the thermistor membrane 60.

With reference to FIG. 1B, intermediate pads 2 intended to form juts, i.e. segments of the intermediate pads 2 that each protrude within each vertical orifice of the supporting pillars, are then produced. To do this, a first intermediate sacrificial layer 72.1 is first of all deposited so as to cover the holder of the supporting pillar (here the thermally insulating arms 30 and the thermistor membrane 60), and the lower sacrificial layer 71. The sacrificial layer 72.1 is made of a mineral material that is identical or similar to the mineral material of the sacrificial layer 71.

The intermediate pads 2, which are made of a material that is sensitive to (i.e. that is capable of being etched by) the etchant used subsequently to remove the various sacrificial layers, are then produced on the upper face of the first intermediate sacrificial layer 72.1. This material may be chosen from titanium, tantalum oxide (Ta₂O₅), and a silicon nitride that is preferably deposited by PECVD at low temperature, at 300° C. for example, inter alia. They have a thickness that depends on the nature and on the thickness of the sacrificial layers 72.1, 72.2 to be etched, and may be of the order of a few tens of nanometers to a few hundred nanometers in thickness, and for example comprised between 100 nm and 300 nm in thickness. Each intermediate pad 2 is positioned in the XY-plane so that a segment protrudes into the vertical orifice intended to produce the supporting pillar.

With reference to FIGS. 1C and 1D, the vertical orifices 51 intended to form the hollow supporting pillars are then produced. To do this, a second intermediate mineral sacrificial layer 72.2 is first of all deposited so as to cover the subjacent sacrificial layer 72.1 and the intermediate pads 2 intended to form the juts 2a. The thickness of the two intermediate sacrificial layers 72.1, 72.2 makes it possible to define the distance separating the detecting element (absorber) from the thermistor membrane 60, and thus to define, with the sacrificial layer 71, the size along the Z-axis of the quarter-wave interference cavity between the absorber and the reflector 40. The second intermediate sacrificial layer 72.2 may then be covered with an etch-stop layer 81, which is for example made of SiN or equivalent.

Next, the vertical orifices 51 are produced by photolithography and etching, and pass through, from top to bottom, the etch-stop layer 81 where appropriate, and the second and first intermediate sacrificial layers 72.2, 72.1, so as to open onto the holder of the supporting pillar, here onto the thermistor membrane 60. Each vertical orifice 51 is bounded transversely by a lateral border 51a, which extends substantially parallel to the Z-axis. To obtain the protrusion of each jut 2a with respect to the lateral border 51a of the vertical orifice 51, and more precisely under the jut 2a along the Z-axis, the etch of the intermediate sacrificial layers 72.1, 72.2, and in particular the etch of the first intermediate sacrificial layer 72.1, is slightly isotropic. The etching may be of the reactive ion etching (RIE) type. Moreover, the vertical orifices 51 may have, in the plane (X, Y), a cross section of square, rectangular or circular shape, with an area substantially equal, for example, to 0.25 μm². They may have a dimension in the XY-plane of the order of about 0.5 μm, and a height comprised between about 0.5 μm and 1.5 μm, and for example equal to about 1 μm, in the context of detection of infrared in the LWIR range.

Due to the prior positioning of each intermediate pad 2, a segment then protrudes with respect to the lateral border 51a of each vertical orifice 51. This segment therefore forms a jut 2a, i.e. a protruding segment intended to cause a local break in the continuity of the layer of interest deposited subsequently. Preferably, it protrudes with respect to the lateral border 51a over a distance in the XY-plane at least larger than the thickness that the layer of interest is intended to have in the lateral border 51a (forming vertical walls of the supporting pillar). Thus, in the case where these vertical walls are intended to have an average thickness of about 50 nm, the jut 2a then protrudes over a distance preferably at least equal to 50 nm. Preferably, to preserve the mechanical strength of the supporting pillar, the jut 2a may extend over at most half of the local circumference of the vertical orifice 51.

With reference to FIG. 1E, the supporting pillars 50 intended to keep the detecting elements (here, the absorbers) suspended are produced. To do this, a layer of interest 52 is deposited so that it covers the lateral border 51a of the vertical orifice 51 and makes contact with the holder, in this case contact with the thermistor membrane 60. The layer of interest 52 is deposited using a conformal deposition technique. It is for example deposited by chemical vapor deposition, or even by physical vapor deposition (e.g. sputtering), inter alia. The layer of interest is made of at least one material chosen from a tungsten silicide (WSi), TiN, and TiW, inter alia.

The inventors have thus observed that, when such a layer of interest (made of WSi, TiN, etc.) is deposited in a conformal manner, preferably by CVD, in the vertical orifice 51 into which the jut 2a protrudes, a local break occurs in the continuity of the layer of interest 52 under the jut 2a. A lateral aperture 54a that will be used subsequently to remove the sacrificial filling layer that will be present in the internal space 53 of the supporting pillar 50 is therefore formed.

So as to form hollow supporting pillars 50, the layer of interest has a thickness smaller than the lateral dimension of the vertical orifice 51 in the XY-plane, so that this vertical orifice 51 is not completely filled by the material of the layer of interest 52. By way of example, the layer of interest 52 may have a substantially constant thickness of a few tens of nanometers to a few hundred nanometers (of about 150 nm for example) in an XY-plane, and for example of 50 nm in a plane substantially orthogonal to the XY-plane, whereas the vertical orifice 51 may have a lateral dimension equal, for example, to about 0.5 μm. Thus, the supporting pillars 50 are formed by a layer 52 that extends vertically along the Z-axis, except at the lateral aperture 54a, which laterally delineates an empty internal space 53. This internal space 53 opens onto an upper aperture 54b in the +Z-direction. The supporting pillars 50 therefore comprise vertical walls 50a that extend over the lateral border 51a of the vertical orifice 51, and that are connected together by a lower holder wall 50b that is located opposite the upper aperture 54b and that rests on and in contact with the thermistor membrane 60. The vertical walls 50a of the supporting pillars 50 here extend substantially orthogonally to the XY-plane of the readout substrate 10.

With reference to FIG. 1F, a mineral sacrificial filling layer 73 is then deposited, so as to cover the layer of interest 52 and to fill the internal space 53 of the supporting pillars 50. The sacrificial filling layer 73 is preferably made of a mineral dielectric that is identical to the dielectric of the subjacent sacrificial layers. It comprises an upper segment 73b that covers the peripheral portion 52a of the layer of interest 52, which extends over the etch-stop layer 81, and a lower segment 73a located in the internal space 53. An essentially flat surface is thus obtained that facilitates the subsequent technological operations.

With reference to FIG. 1G, the upper segment 73b of the sacrificial filling layer 73 is then removed to expose the upper face of the peripheral portion 52a of the layer of interest 52. Next, via selective etching, the peripheral portion 52a and then the etch-stop layer 81 are removed. Thus, the upper face of the second intermediate sacrificial layer 72.2 is freed (i.e. uncovered) while a portion of the lower segment 73a of the sacrificial filling layer is left protruding with respect to the free upper face of the second intermediate sacrificial layer 72.2. The upper end along the Z-axis of the vertical walls 50a of the supporting pillars 50 is also freed.

With reference to FIG. 1H, the detecting element, namely here the absorber 80, of each thermal detector is then produced. To do this, a continuous layer made of a material able to absorb the electromagnetic radiation to be detected is deposited, so as to cover the upper face of the sacrificial layer 72.2, the free end of the vertical walls 50a of the supporting pillars 50, and the lower segment 73a of the sacrificial filling layer. This layer may be covered by, may cover, or be encapsulated in an additional thin layer allowing the stiffness of the absorber 80 to be increased. This additional layer may be made of a dielectric, of amorphous silicon for example. The thickness of the absorbent layer 80 is chosen so as to match its impedance to that of free space (resistivity of the absorbent layer close to 377 Ω/sq). The absorbent layer is then etched in a localized manner, so as thus to obtain the absorber 80 of the thermal detector, which is thus situated facing the reflector 40. Clearly, as a result of the above the absorber 80 extends continuously and in a substantially planar manner above the reflector 40. It therefore obturates the upper aperture 54b of the supporting pillar 50.

With reference to FIG. 1I, the suspension above the readout substrate 10 of the absorber 80 of each thermal detector 20, and here more broadly of the three-dimensional structures 22, is obtained. To do this, the various mineral sacrificial layers 71, 72.1, 72.2, 73 are removed by chemical etching. The suspension is more precisely obtained by wet chemical etching in an acidic medium of the various mineral sacrificial layers, here with hydrofluoric-acid vapor. The lower segment 73a of the sacrificial filling layer 73 is removed at the same time, through the lateral through-aperture 54a in the supporting pillars 50, and not through the upper aperture 54b since the latter is obturated. The intermediate pads 2 forming the juts 2a are also removed, insofar as they are made of a material sensitive to the etchant used, this making it possible to prevent them from degrading the performance of the detecting device 1 by falling onto the membranes made of thermistor material or remaining fastened to the supporting pillars 50 (and therefore disrupting the electromagnetic radiation in the optical cavity).

Thus, the fabricating process allows a detecting device 1 to be obtained the performance of which is optimized and the matrix of sensitive pixels of which may have a particularly small pixel pitch. Specifically, the supporting pillars 50 are hollow, i.e. they are not filled with the material of the layer of interest 52 or with that of the sacrificial filling layer 73. Thus, they have a particularly low thermal mass, this contributing to decreasing the thermal time constant of the thermal detectors 20. In addition, the absorber here extends in a substantially planar manner and has a large absorption area, thus allowing an optimized quarter-wave interference cavity to be formed, this contributing to improving the performance of the thermal detector 20.

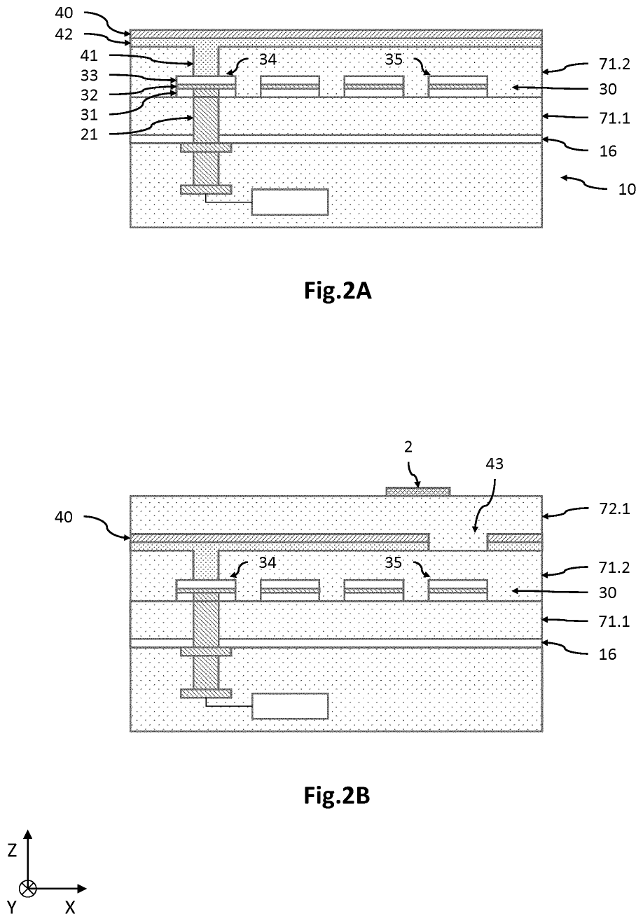

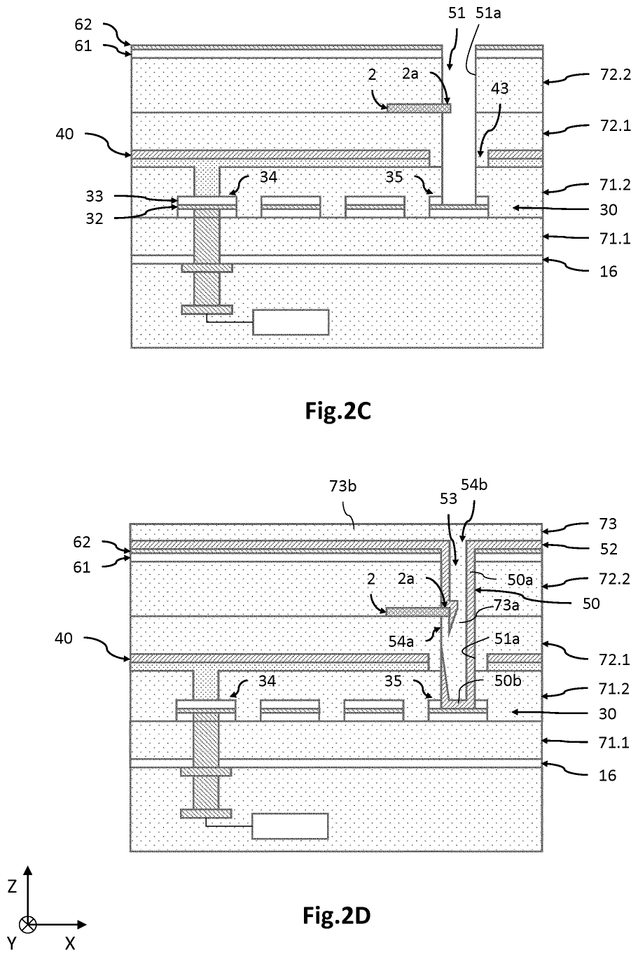

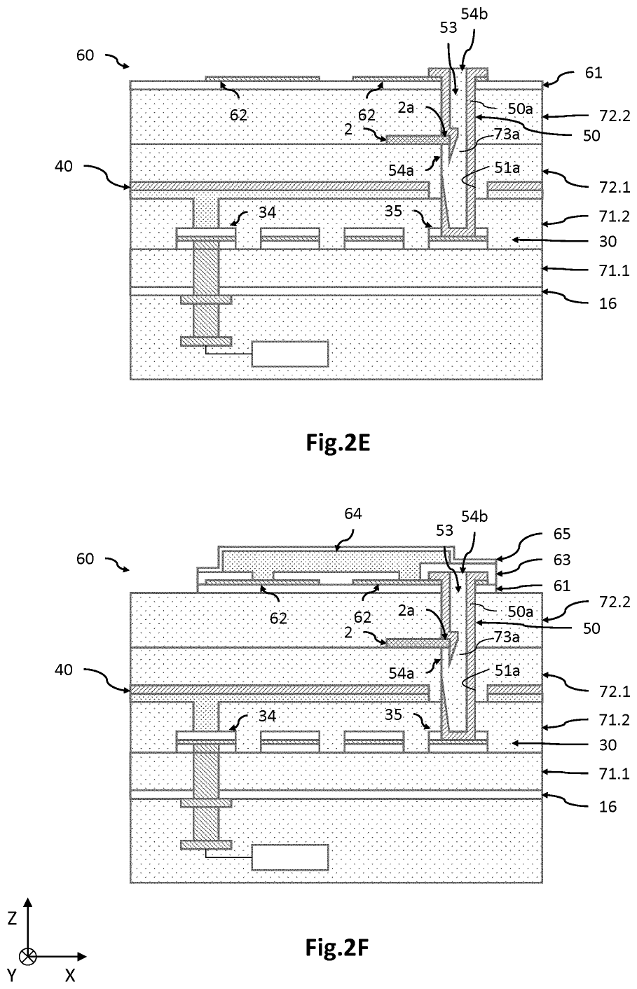

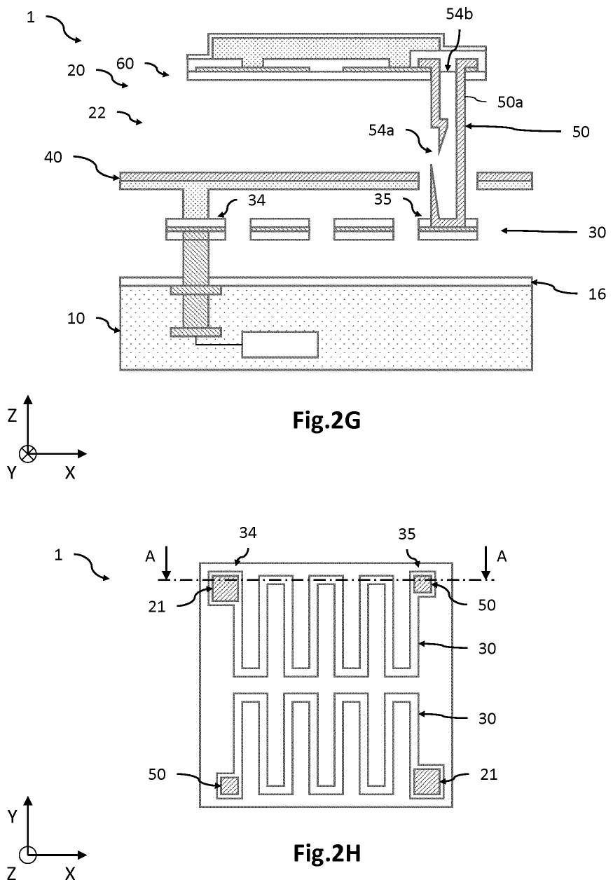

FIGS. 2A to 2H illustrate various steps of a process for fabricating the detecting device 1 according to a second embodiment. The detecting device 1 is similar to that illustrated in FIG. 1I and differs from it essentially in that the detecting element is here an absorbent membrane 60 made of thermistor material. This membrane is suspended by one or more supporting pillars 50, which also participate in connecting the thermistor material 64 to the readout circuit 12. In addition, the reflector 40 is not placed on and in contact with the readout substrate 10, but is rather located in an intermediate stage of the three-dimensional structure 22.

More precisely, the thermal detector 20 here comprises a three-dimensional structure 22 containing three separate stages that are superposed on one another and suspended above the substrate by the anchoring pillars 21: the lower stage comprises the thermally insulating arms 30, an intermediate stage comprises the reflector 40, and an upper stage comprises the detecting element (here the thermistor absorbent membrane 60), which is suspended by supporting pillars 50. In this example, the supporting pillars 50 are hollow pillars the upper apertures 54b of which are obturated by the absorbent membrane 60, and that each comprise a lateral aperture 54a allowing removal, from the side, of a sacrificial filling layer 73 initially located in the internal space 53 of the supporting pillar 50.

With reference to FIG. 2A, first of all the lower and intermediate stages of the three-dimensional structure are produced. The readout substrate 10 is identical or similar to that described with reference to FIG. 1A and is not described again in detail. The protective layer 16 is covered by a first lower sacrificial layer 71.1, which is made of a mineral material. On the sacrificial layer 71.1 rest the thermally insulating arms 30, which here form a serpentine between a first end 34 making contact with an anchoring pillar 21, and a second end 35 intended to serve as a holder for the supporting pillar of the detecting element (here the absorbent membrane 60). The thermally insulating arms 30 are formed from a stack of a lower dielectric layer 31, of a conductive layer 32, and of an upper dielectric layer 33, and are suspended above the readout substrate 10 by the anchoring pillars 21.

To then produce the intermediate stage, a second lower mineral sacrificial layer 71.2 is deposited so as to cover the subjacent sacrificial layer 71.1 and the thermally insulating arms 30. The thickness of the sacrificial layer 71.2 allows the distance separating the lower and intermediate stages of the three-dimensional structure, i.e. the reflector 40 from the thermally insulating arms 30, to be defined. This distance may be of the order of a few hundred nanometers to a few microns, and for example is comprised between 500 nm and 5 μm, and preferably comprised between 1 μm and 2 μm.

Vertical orifices intended for the formation of the supporting pads 41 that support the reflector 40 are then produced. They are produced by photolithography and etching, and pass through the second lower sacrificial layer 71.2 in such a way as to open onto the thermally insulating arms 30, and preferably onto the first end 34 of the thermally insulating arms 30 resting on the anchoring pillars 21, so that the supporting pads 41 are preferably located opposite the anchoring pillars 21. As a variant, each supporting pad 41 may rest on and in contact with the readout substrate 10, and not on a thermally insulating arm 30. In this example, a continuous supporting layer 42, which is preferably made of a dielectric such as amorphous silicon, is then deposited so as to fill the vertical orifices and to cover the second lower sacrificial layer 71.2. The supporting layer 42 is then covered with a reflective layer that forms the reflector 40 and that is made of a material that is reflective to the electromagnetic radiation of interest, for example a metal layer made of aluminum, copper, or tungsten, inter alia. The supporting layer 42 and the reflector 40 may extend continuously over all the sensitive pixels, or be separate from one sensitive pixel to the next.

With reference to FIG. 2B, intermediate pads 2 intended to form juts are then produced. This step is here identical or similar to that described above with reference to FIG. 1B and is not detailed again. Beforehand, if necessary, a through-aperture 43 is produced by localized etching of the reflective layer 40 and of the supporting layer 42 perpendicular to the portion of the thermally insulating arms 30 that is intended to receive the supporting pillar 50, here the portion at the second end 35. The intermediate pads 2 are produced on the upper face of a first intermediate mineral sacrificial layer 72.1 deposited beforehand on the reflector 40 and on the subjacent sacrificial layer 71.2 through the through-aperture 43, and are placed so as to subsequently form juts 2a in the vertical orifices 51. The intermediate pads 2 are made of a material that is sensitive to the etchant subsequently used to remove the various sacrificial layers. As indicated above, this material may be chosen from titanium (Ti), tantalum oxide (Ta₂O₅), and a silicon nitride (SiN) that is preferably deposited by PECVD at low temperature, at 300° C. for example, inter alia. They have a thickness of the order of a few hundred nanometers, and for example comprised between 100 nm and 300 nm.

With reference to FIG. 2C, the vertical orifices 51 intended to form the hollow supporting pillars are then produced. To do this, a second intermediate mineral sacrificial layer 72.2 is first of all deposited so as to cover the subjacent sacrificial layer 72.1 and the intermediate pads 2. The thickness of the first and second intermediate sacrificial layers 72.1, 72.2 allows the size along the Z-axis of the quarter-wave interference cavity between the intermediate and upper stages of the three-dimensional structure 22 to be defined.

Next, the lower dielectric layer 61 of the absorbent membrane 60, and the conductive layer 62 intended to form the biasing electrodes, are deposited on the upper face of the second intermediate sacrificial layer 72.2. The lower dielectric layer 61 may be made of at least one dielectric. By way of example, it may be formed, for example, from a thin protective sublayer for protecting against subsequent chemical etching, which layer is for example made of amorphous silicon, of Al₂O₃ or of AlN with a thickness comprised between 10 nm and 50 nm, and optionally coated with a passivating sublayer, which is for example made of SiN (notably when the thin protective sublayer is made of amorphous silicon) with a thickness comprised between 10 nm and 30 nm. The material of the conductive layer 62 is furthermore absorbent with respect to the electromagnetic radiation to be detected: this conductive layer 62 is intended to form the absorber, in addition to the biasing electrodes. This layer is preferably made of Ti, TiN, TaN, or WN, inter alia, and has a thickness comprised between about 3 nm and 20 nm. Here it covers the lower dielectric layer 61.

Next, the vertical orifices 51 intended for the formation of the hollow supporting pillars 50 are produced. They are produced by photolithography and etching, and pass through, from top to bottom, the conductive layer 62, the lower dielectric layer 61, the second and first intermediate sacrificial layers 72.2, 72.1, the second lower sacrificial layer 71.2, and the upper dielectric layer 33, in order thus to open onto the conductive layer 32 of the thermally insulating arms 30, here at the second end 35. To obtain the protrusion of the jut 2a with respect to the lateral border 51a of each vertical orifice 51, and more precisely under the jut 2a along the Z-axis, the etch of the sacrificial layers, and in particular the etch of the first intermediate sacrificial layer 72.1 and/or 71.2, is slightly isotropic.

As indicated above, a segment of the intermediate pad 2 then protrudes with respect to the lateral border 51a of each vertical orifice 51. This segment therefore forms a jut 2a. The jut 2a preferably protrudes with respect to the lateral border 51a over a distance in the XY-plane at least larger than the thickness that the layer of interest 52 is intended to have in the lateral border 51a. Thus, in the case of vertical walls 50a of the supporting pillar 50 that are intended to have an average thickness of about 50 nm, the jut 2a then protrudes over a distance advantageously at least equal to 50 nm. Preferably, to preserve the mechanical strength of the supporting pillar 50, the jut 2a may extend over at most half of the local circumference of the vertical orifice.

With reference to FIG. 2D, the supporting pillars 50 intended to hold the absorbent membranes suspended, and to connect them to the readout circuit 12, are produced. To do this, a layer of interest 52 is first of all deposited so that it covers the lateral border 51a of each vertical orifice 51 and makes contact on the one hand with the conductive layer 32 of the thermally insulating arms 30, and on the other hand with the conductive layer 62 intended to form the biasing electrodes. The layer of interest 52 is deposited using a conformal deposition technique. It is for example deposited by chemical vapor deposition (CVD), or even by physical vapor deposition (PVD) (e.g. sputtering), inter alia. This layer is made of an electrically conductive material here chosen from WSi, TiN, and TiW, inter alia.

As described above, the conformal deposition, preferably by CVD, of such a layer of interest 52 (made of WSi, of TiN, etc.) in the vertical orifice 51 into which the jut 2a protrudes, results in a local break in the continuity of the layer of interest 52, notably under the jut 2a. A lateral aperture 54a that will be used subsequently to remove the sacrificial filling layer 73 that will be present in the internal space 53 of the conductive pillar is therefore formed. Thus, the supporting pillars 50 make electrical contact with the readout circuit 12 via the anchoring pillars 21 and the thermally insulating arms 30, and allow the biasing electrodes 62 to be connected. They comprise vertical walls 50a that are connected together by a lower holder wall 50b, which rests on and in contact with the thermally insulating arms 30. The internal space 53 bounded transversely by the vertical walls 50a opens onto an upper aperture 54b that lies opposite the holder wall 50b in the +Z-direction.

Lastly, a mineral sacrificial filling layer 73 is deposited so as to cover the layer of interest 52 forming the supporting pillars 50 and to fill the internal space 53 of the latter. The sacrificial layer 73 is preferably made of a dielectric that is identical to the dielectric of the subjacent sacrificial layers. It therefore comprises an upper segment 73b covering the peripheral portion 52a of the layer of interest 52, and a lower segment 73a filling the internal space 53 of the supporting pillars 50.

With reference to FIG. 2E, production of the detecting element, namely here the absorbent thermistor membrane 60 that forms the upper stage of the three-dimensional structure 22, is continued. To this end, the upper segment 73b of the sacrificial filling layer 73 is removed so as to expose the upper face of the layer of interest 52. The lower segment 73a of the sacrificial filling layer 73 is thus preserved. This segment is flush, parallel to the XY-plane, with the peripheral portion 52a of the layer of interest 52. An essentially planar surface is thus obtained that facilitates the subsequent technological operations (otherwise it would be necessary to remove the layers that could fall into the internal space 53 of the supporting pillars 50).

Next, by photolithography and etching, the conductive layer 62 is structured in the XY-plane so as to define the biasing electrodes. The peripheral portion 52a of the layer of interest 52 is also etched, so as to keep only an upper segment that makes contact with the biasing electrodes 62. The biasing electrodes 62 are substantially coplanar and electrically insulated from each other. They are produced so as to have a resistivity of the order of 377 Ω/sq. The biasing electrodes 62 each make contact with a different supporting pillar 50 and are separated from each other in the XY-plane by a distance that is preferably smaller than about λ_{c}/5 or even smaller than 1 μm. Preferably, the material of the electrodes 62 is different from that of the layer of interest 52, so as to obtain an etch selectivity between these two materials. Thus, the electrodes 62 may be made of TiN and the layer of interest 52 may be made of WSi.

With reference to FIG. 2F, production of the absorbent membrane 60 is completed. Thus, via a series of depositing, photolithography and etching steps, the intermediate insulating layer 63, which is made of a dielectric, of Al₂O₃ or AlN for example, and which covers the electrodes 62 and the lateral spacing therebetween, except level with apertures that open onto the electrodes 62, is produced. A segment of thermistor material 64, for example amorphous silicon or an oxide of vanadium or titanium, is deposited in electrical contact with the electrodes 62 via the apertures. It may for example have a thickness comprised between 50 nm and 200 nm. Lastly, an upper protective layer 65, for example made of amorphous silicon, Al₂O₃ or AlN with a thickness comprised between 10 nm and 50 nm, is deposited so as to cover the thermistor material 64 so as to protect it from the chemical attack implemented subsequently.

Thus, the absorbent membrane 60 is suspended by the supporting pillars 50, which also connect the thermistor material 64 to the readout circuit 12. The absorbent membrane 60, and more precisely here the intermediate dielectric layer 63, covers the upper aperture 54b of each conductive pillar. This aperture is then obturated and does not allow the sacrificial filling layer 73 to be evacuated.

With reference to FIGS. 2G and 2H, the sacrificial layers 71.1, 71.2, 72.1, 72.2, 73 are removed, so as to suspend the three-dimensional structure 22 above the readout substrate 10. The suspension is obtained here by chemically etching the various mineral sacrificial layers, here by wet chemical etching in hydrofluoric-acid vapor. The lower segment 73a of the sacrificial filling layer 73 is evacuated at the same time, through the lateral through-aperture 54a of the supporting pillars 50, and the intermediate pads 2 are also removed insofar as they are made of a material sensitive to the etchant used, this preventing them from degrading the performance of the detecting device 1.

A detecting device 1 here comprising a matrix array of sensitive pixels that may have a particularly small pixel pitch, each sensitive pixel having a low time constant, is thus obtained. Specifically, the supporting pillars 50 are hollow, this allowing the thermal mass of the supporting pillars 50 to be decreased and thus the thermal time constant of the thermal detectors 20 to be decreased. In addition, the pixel pitch may be particularly small. Although the upper aperture 54b of the supporting pillars 50 is obturated by the absorbent membrane 60, the sacrificial filling layer 73 may be effectively evacuated out of the internal space 53 through the lateral through-aperture 54a.

Moreover, this embodiment of the detecting device 1 is particularly advantageous insofar as the quarter-wave interference cavity has an optimal performance. Specifically, this vertical arrangement of the various functional stages of thermal insulation, optical reflection, and absorption/detection of the electromagnetic radiation of interest both allows a sensitive pixel of small lateral dimensions in the XY-plane, for example of lateral dimensions of the order of ten microns or even less, to be produced and the performance of the thermal detector 20 to be optimized. Specifically, it is possible to improve the thermal insulation of the absorbent membrane 60 (and therefore to increase the thermal resistance of the thermal detector 20) by producing thermally insulating arms 30 of a considerable length in the plane of the first stage insofar as there is no constraint as regards the presence of the absorbent membrane 60. In addition, the thermal detector 20 has a large fill factor (FF), this parameter FF being defined as the ratio of the area of the absorbent membrane to the total area of the sensitive pixel, in an XY-plane parallel to the plane of the substrate. The fill factor FF is particularly high insofar as the absorbent membrane 60 is not limited in size by the presence of the thermally insulating arms 30 in the plane of the third stage. Thus, the optical efficiency of the thermal detector 20, which is the product of the parameter FF multiplied by the absorption e of the thermal detector 20, is preserved, the absorption e being defined as the proportion absorbed per unit area of the incident energy of the electromagnetic radiation to be detected.

In addition, the fact that the thermally insulating arms 30 are located in the lower stage and not in the intermediate stage, and therefore are located outside the quarter-wave interference cavity, allows the performance of the thermal detector 20 to be preserved. Specifically, the presence of the thermally insulating arms 30 in the quarter-wave interference cavity may lead to disruption of the interference cavity and consequently to a degradation of the absorption e. The absorber 62 of the absorbent membrane 60 is conventionally placed at a distance from the reflector 40 such that the reflected wave generates constructive interference with the wave incident on the absorbent membrane 60, i.e. at a distance substantially equal to λ_{c}/4n from the reflector, λ_{c} being a central wavelength of the spectral range of the electromagnetic radiation to be detected (for example 10 μm for the LWIR range), and n being the refractive index of the medium located in the quarter-wave interference cavity, which is usually a vacuum. However, the presence of the thermally insulating arms 30 within the quarter-wave interference cavity may lead to a decrease in the absorption e of the thermal detector 20, on the one hand due to a modification of the optical path allowing constructive interference to occur at the absorbent membrane, and on the other hand due to a non-zero absorption of electromagnetic radiation by the thermally insulating arms 30. Clearly, as a result of the above these drawbacks are here avoided insofar as the thermally insulating arms 30 are placed outside the quarter-wave interference cavity. The performance of the thermal detector 20 is thus preserved.

Particular embodiments have just been described. Various modifications and variants will appear obvious to those skilled in the art.

1: A process for fabricating a device for detecting electromagnetic radiation, the detecting device comprising:
a substrate comprising a readout circuit; and
at least one thermal detector resting on the substrate and connected to the readout circuit, comprising a detecting element suspended above the substrate by at least one supporting pillar;
the process comprising the following steps:
depositing, on the substrate, a first sacrificial layer;
producing, on the first sacrificial layer, at least one intermediate pad intended to form a jut, the intermediate pad being made of at least one material sensitive to a chemical etchant used subsequently to etch sacrificial layers;
depositing, on the first sacrificial layer and the intermediate pad, a second sacrificial layer;
producing, by locally etching the first and second sacrificial layers, at least one vertical orifice that is bounded transversely by a lateral border, said orifice being positioned so that a segment of the intermediate pad protrudes into the vertical orifice, thus forming a jut;
carrying out conformal deposition, on the lateral border of the vertical orifice, of a layer of interest used to form the supporting pillar, the layer of interest defining an empty internal space of the supporting pillar, the jut causing a local break in the continuity of the layer of interest, forming a lateral through-aperture in the supporting pillar;
depositing a sacrificial filling layer, so as to fill the empty internal space of the supporting pillar;
producing, on the second sacrificial layer and the sacrificial filling layer, the detecting element, which rests on and in contact with the supporting pillar; and
suspending the detecting element by etching said sacrificial layers and the intermediate pad using said etchant, the sacrificial filling layer then being etched through the lateral through-aperture.

2: The fabricating process as claimed in claim 1, wherein the internal space of the supporting pillar opens onto an upper aperture located opposite the substrate, said upper aperture being obturated by the detecting element.

3: The fabricating process as claimed in claim 1, wherein the layer of interest has, on the lateral border of the vertical orifice, an average thickness, the jut protruding with respect to the lateral border by a distance at least equal to said average thickness.

4: The fabricating process as claimed in claim 1, wherein the intermediate pad is made of a material chosen from Ti, Ta₂O₅, and silicon nitride.

5: The fabricating process as claimed in claim 1, wherein the layer of interest is deposited by chemical vapor deposition.

6: The fabricating process as claimed in claim 1, wherein the layer of interest is made of a material chosen from WSi, TiN and TiW.

7: The fabricating process as claimed in claim 1, wherein the sacrificial layers are made of a mineral material, and are removed by wet chemical etching in an acidic medium.

8: The fabricating process as claimed in claim 1, wherein, the sacrificial filling layer comprises an upper segment that covers a peripheral segment of the layer of interest, the peripheral segment covering an upper face of the second sacrificial layer around the vertical orifice, and a lower segment that fills the internal space of the supporting pillar.

9: The fabricating process as claimed in claim 8, comprising a step of removing the upper segment of the sacrificial filling layer, so that the lower segment is flush with the peripheral portion of the layer of interest.

10: The fabricating process as claimed in claim 1, wherein the detecting element is an absorber of the electromagnetic radiation to be detected, the supporting pillar resting on and in contact with a membrane that comprises a thermometric transducer and that is suspended above the substrate by thermally insulating arms, a reflector resting on and in contact with the substrate.

11: The fabricating process as claimed in claim 1, wherein the detecting element is an absorbent membrane that absorbs the electromagnetic radiation to be detected and that comprises a thermometric transducer, the supporting pillar resting on and in contact with a thermally insulating arm suspended above the substrate by an anchoring pillar, a reflector being placed between the absorbent membrane and the thermally insulating arm.
